(19) United States
(12) Patent Application Publication
(10) Pub. No.: US 2026/0156924 A1
(43) Pub. Date: Jun. 4, 2026

(54) POWERLESS EVENT MONITOR

(71) Applicant: Tower Semiconductor Ltd., Migdal Haemek (IL)

(72) Inventors: Yakov Roizin, Afula (IL); Evgeny Pikhay, Haifa (IL)

(73) Assignee: Tower Semiconductor Ltd., Migdal Haemek (IL)

(21) Appl. No.: 18/967,638

(22) Filed: Dec. 3, 2024

(51) Int. Cl. H10D 30/68; H10D 30/69; H10N 10/10; H10N 30/30

(52) U.S. Cl. CPC H10D 84/813; H10D 1/714; H10D 30/68; H10D 86/201

(57) ABSTRACT

A powerless event monitor that includes a keeper device that includes a keeper floating gate, a keeper charging interface that is configured to charge the keeper floating gate before a beginning of a monitoring period, and a keeper discharge path that is triggered to discharge the keeper floating gate upon an occurrence of an event during the monitoring period. The powerless event monitor also includes a timer device that is coupled to the keeper device, that includes a timer floating gate, timer charging interface that is configured to charge the timer floating gate before the beginning of the monitoring period, and (c) a conditional timer floating gate discharge path that is configured to discharge the timer floating gate following at least a partial discharge of the keeper floating gate, wherein a charge of the timer floating gate during the discharging of the time floating gate is indicative of a time lapsed from the occurrence of the event. The timer device is prevented from being powered from a power source external to the powerless event monitor during the monitoring period.

### BACKGROUND OF THE INVENTION

There is a growing need to monitoring events in a cost effective manner.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates examples of powerless monitoring devices;

FIG. 2 illustrates examples of powerless monitoring devices;

FIG. 3 illustrates an example of a timing diagram and of floating gates having fingers;

FIG. 4 illustrates examples of powerless monitoring devices;

FIG. 5 illustrates an example of a method;

FIG. 6 illustrates an example of an array; and

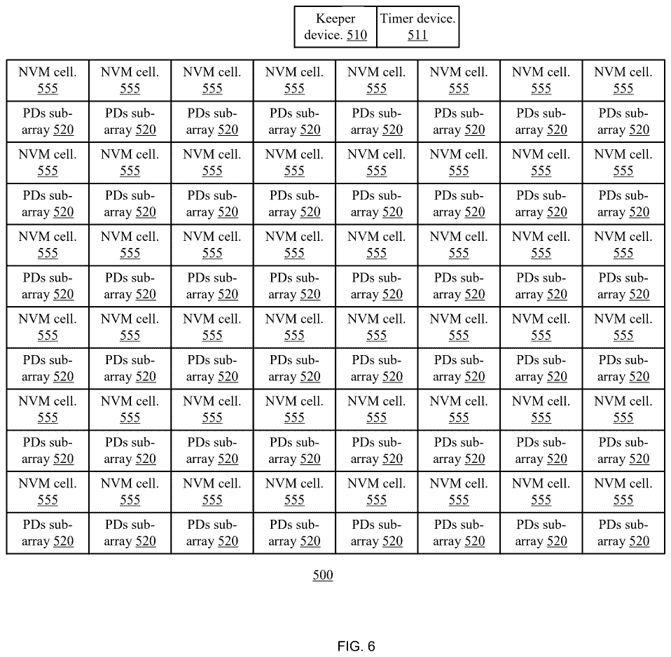

FIG. 7 illustrates examples of keeper devices, event sensing unit, and timer device.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### SUMMARY

Powerless monitoring device and a method for powerless monitoring.

### DESCRIPTION OF THE PREFERRED EMBODIMENTS

According to an embodiment there is provided a powerless event monitor that includes a keeper device and a timer device.

According to an embodiment, the suggested powerless event monitor has a simple structure and does not require to receive power from an external supply source—which dramatically reduces the cost and complexity of monitoring events.

According to an embodiment, the keeper device exhibits a keeper retention time and includes (a) a keeper floating gate, (b) a keeper charging interface that is configured to charge the keeper floating gate before a beginning of a monitoring period, and (c) a keeper discharge path that is triggered to discharge the keeper floating gate upon an occurrence of an event during the monitoring period.

According to an embodiment, the timer device is coupled to the keeper device. The timer device has a timer retention time that is a fraction of the keeper retention time, and comprises (a) a timer floating gate, (b) a timer charging interface that is configured to charge the timer floating gate before the beginning of the monitoring period, and (c) a conditional timer floating gate discharge path that is configured to discharge the timer floating gate following at least a partial discharge of the keeper floating gate.

According to an embodiment, the timer device is coupled to the keeper device by providing a coupling between the keeper floating gate and the timer floating gate.

According to an embodiment, the coupling is a capacitive coupling.

According to an embodiment, at least a portion of the keeper floating gate and at least a portion of the timer floating gate form a capacitor.

According to an embodiment, the keeper floating gate includes keeper floating gate fingers, the timer floating gate includes timer floating gate fingers, wherein the keeper floating gate fingers and the timer floating gate fingers are arranged in an interdigitated configuration—to form a capacitor.

Due to the discharging of the timer device following the occurrence of the event, a charge of the timer floating gate during the discharging of the time floating gate is indicative of a time lapsed from the occurrence of the event.

According to an embodiment the powerless event monitor is powerless in the sense that the timer device is prevented from being powered from a power source external to the powerless event monitor during the monitoring period. The keeper device is not powered by an external power source during the monitoring period—may receive or generate an electrical current due to the occurrence of the event.

According to an embodiment, the keeper retention time is long enough to prevent a discharge of the timer device if the event did not occur during the monitoring period.

According to an embodiment, the timer retention time is short enough to have the charge stored in the timer floating gate reflect the time that lapsed from the occurrence of the event during the monitoring period. For example—the timer retention time may exceed the duration of the monitoring period.

According to an embodiment the occurrence of an event during the monitoring period is made by an event sensing unit.

According to an embodiment the powerless event monitor includes the event sensing unit. According to an embodiment the event sensing unit is a part of the keeper discharge path. According to an embodiment the event sensing unit is not a part of the keeper discharge path. According to an embodiment the event sensing unit and the keeper discharge unit share at least one component. According to an embodiment, at least a part of the event sensing unit is located within the keeper floating gate. According to an embodiment, at least a part of the event sensing unit is located outside the keeper floating gate.

According to an embodiment, the powerless event monitor does not include the event sensing unit.

According to an embodiment, the keeper device is in communication with an event sensing unit that is configured to sense the occurrence of the event. Accordingly the keeper discharge path is configured to receive a signal from the event sensing unit that triggers the discharging of the keeper floating gate.

According to an embodiment, the sensing of the event includes sensing at least one of radiation, temperature, pressure, a change of radiation, a change of temperature, a change of position, and the like.

According to an embodiment, a movement of a monitored element may be detected by a movement sensor such as a piezoelectric generator that is shaped and positioned to undergo a pressure difference when the monitored element is moved and/or by detecting radiation that is changed (for example—having a radiations source be concealed or exposed due to said movement). A monitored element may be a door—for example a door of a safe, a room or an area that should not be entered without authorization, and the like.

According to an embodiment, the event sensing unit includes one or more photodiodes that are configured to generate current when exposed to radiation.

According to an embodiment, the event sensing unit includes a piezoelectric generator configured to generate an electrical signal under pressure, the pressure being indicative of the occurrence of the event.

According to an embodiment, the event sensing unit includes a Seebeck thermal electrical generator.

According to an embodiment, the event sensing unit is configured to sense an event that includes a temperature change.

According to an embodiment, the event sensing unit comprises a dielectric layer with temperature dependent conductivity that is formed on the keeper floating gate.

According to an embodiment, the different retention times of the keeper device and the timer device are attributed to differences in the thickness of their respective tunneling oxide layers that are adjacent to their respective floating gates.

For example—a timer oxide layer has a thickness that ranges between thirty to fifty Angstrom, and wherein keeper oxide layer thickness ranges between seventy to one hundred and thirty Angstrom.

For example—a ratio between the thickness of the timer oxide layer and thickness of the keeper oxide layer ranges between one and a half and four, two and a half to three, and the like.

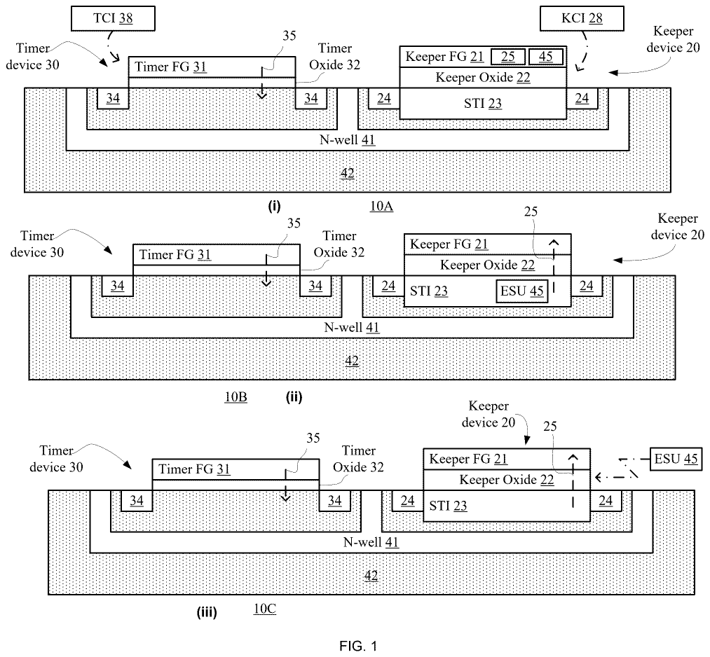

FIG. 1 illustrates three examples ((i), (ii) and (iii) of powerless event monitors —denoted 10A, 10B and 10C.

In all three examples the powerless monitoring system is illustrated as including keeper device 20 and timer device 30. Keeper device 20 includes (from top to bottom —keeper FG 21, keeper oxide 22, and N-diffusions 24. Timer device includes (from top to bottom)—timer FG 31, timer oxide 32, N-diffusions 23. Both keeper device 20 and timer device 30 are formed on (and may include a portion of) a P-type substrate 42 and are surrounded by an N-well 41. (When using an N-type substrate, the well is a P-well).

In all three examples the conditional timer floating gate discharge path (denoted 35) passes through the timer device.

The powerless event monitors 10A, 10B and 10C differ from each other by the location and/or type of the event sensing unit (denoted ESU) 45 and the keeper discharge path 25.

For simplicity of explanation only example (i) illustrates the keeper charging interface (denoted KCI 28) that is configured to charge the keeper floating gate before a beginning of a monitoring period, and timer charging interface (denoted TCI 38) that is configured to charge the timer floating gate before the beginning of the monitoring period.

In example (i)—ESU 45 and keeper discharge path 25 are located at the keeper floating gate (denoted keeper FG 21).

In example (ii) the ESU 45 is located below the keeper oxide 22—for example near or within the shallow trench isolation (denoted STI 23), and the keeper discharge path associated with a keeper discharge path 25 passes through a keeper floating gate transistor that includes the keeper FG gate 21, the keeper oxide 22, and other layers.

In example (iii) the ESU 45 is located outside the powerless monitoring system and is in communication with the keeper device—to provide signal indicative of the occurrence of the event. According to an embodiment, most of the charge is in the FG over thick oxide denoted STI 23 and ESU45 is located outside the powerless monitoring system and is in communication with the keeper device—to provide signal indicative of the occurrence of the event.

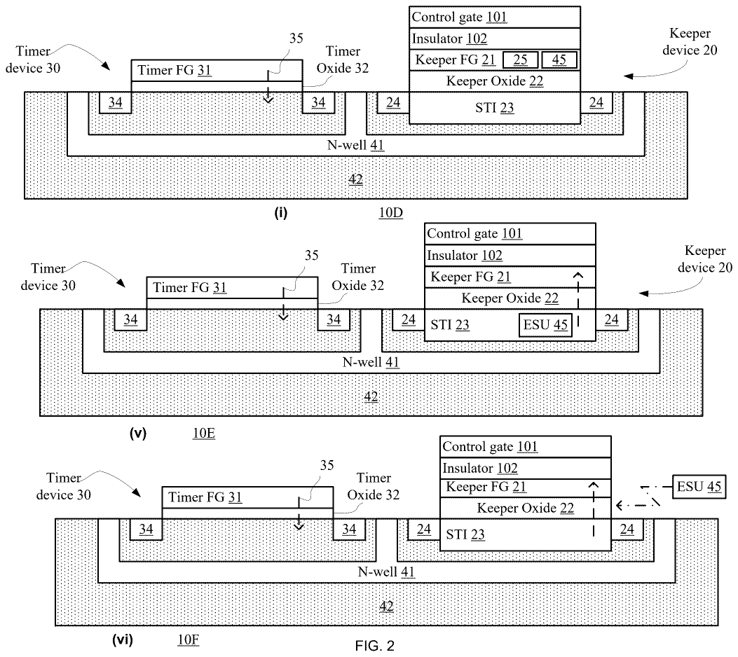

FIG. 2 illustrates that a control gate 101 (can be made of metal) and an insulator 102 may be located above the keeper FG 21. Example (iv) of FIG. 2 corresponds to example (i) plus the addition of the control gate 101 and the insulator 102. Example (v) of FIG. 2 corresponds to example (ii) plus the addition of the control gate 101 and the insulator 102. Example (vi) of FIG. 2 corresponds to example (iii) plus the addition of the control gate 101 and the insulator 102.

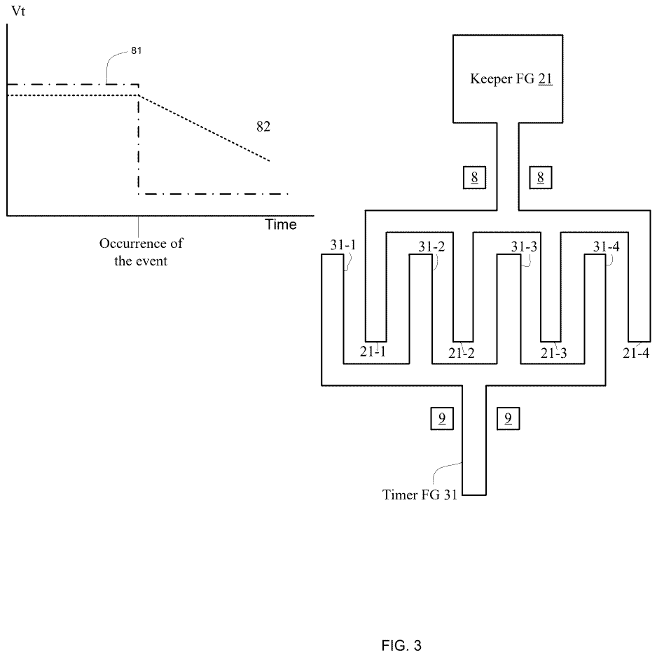

FIG. 3 is a top view of keeper FG 21 and timer FG 31. Keeper FG 21 includes keeper floating gate fingers 21-1, 21-2, 21-3 and 21-4. Timer FG 31 includes timer floating gate fingers 31-1, 31-2, 31-3 and 31-4. The keeper floating gate fingers and the timer floating gate fingers are arranged in an interdigitated configuration—to form a capacitor.

FIG. 3 also illustrates:
a. Nodes 8 of a keeper floating gate read transistor configured to read the threshold voltage Vt of the keeper device—which is indicative of the charge stored in the keeper floating gate.
b. Nodes 9 of a timer floating gate read transistor configured to read the threshold voltage Vt of the timer device—which is indicative of the charge stored in the timer floating gate.
c. A time diagram illustrating the Vt of the keeper device (see lines 81) —which immediately turns from a keeper charged Vt value to a keeper uncharged Vt upon the occurrence of the event and the Vt of the timer device (see lines 82)—which gradually decreases—following the occurrence of the event.

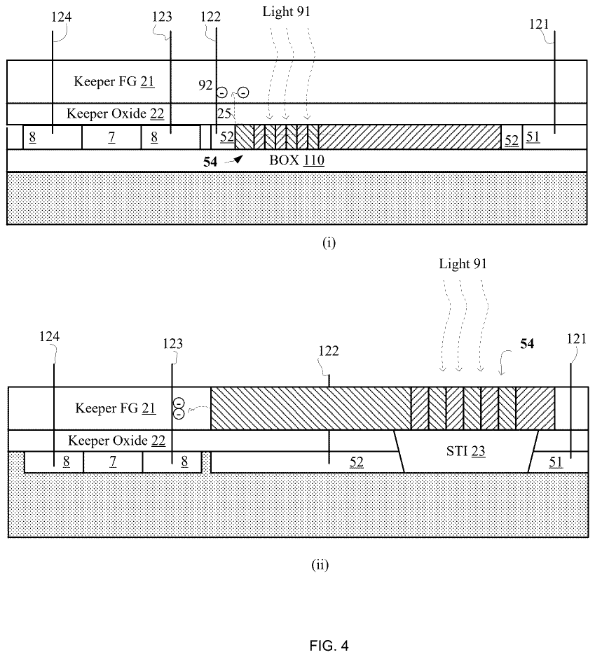

FIG. 4 illustrates two examples of event sensing units, keeper discharge paths, and of nodes (denoted 8 and 7) of a keeper floating gate reader transistor in connection with vertical conductors. Control electrodes 121 and 122 are in contact with transfer gate 51 and control gate 52 respectively and are used to control the keeper FG 21—for example—for initially charging the keeper FG before being discharged. Read electrodes 123 and 124 are used to read the keeper floating gate reader transistor and are in contact with nodes 8. In example (i) there is a buried oxide layer (BOX 110) between the substrate and each one of the transfer gate, control gate 52, and nodes 7 and 8.

In example (i) the event sensing unit is a sequence of radiation sensors such as photodiodes 54 that once illuminated with radiation (such as light 91) generate a current that passes through a keeper discharge path 25 (that includes keeper oxide 22) and inject electrons 92 to keeper FG 21—and discharge the positive charge of keeper FG 21. The photodiodes are positioned between a right side segment of control gate 52 and a left side segment of control gate 52 that has a smaller area than the left side segment of the control gate 52—and the current flows to the left of the photodiodes—as illustrated in FIG. 3.

In example (ii) the event sensing unit is a sequence of radiation sensors such as photodiodes 54 that also form a part of the keeper discharge path. Once illuminated with radiation (such as light 91) the photodiodes generate a current that passes through the keeper FG 21 and inject electrons 92 to keeper FG 21—and discharge the positive charge of keeper FG 21.

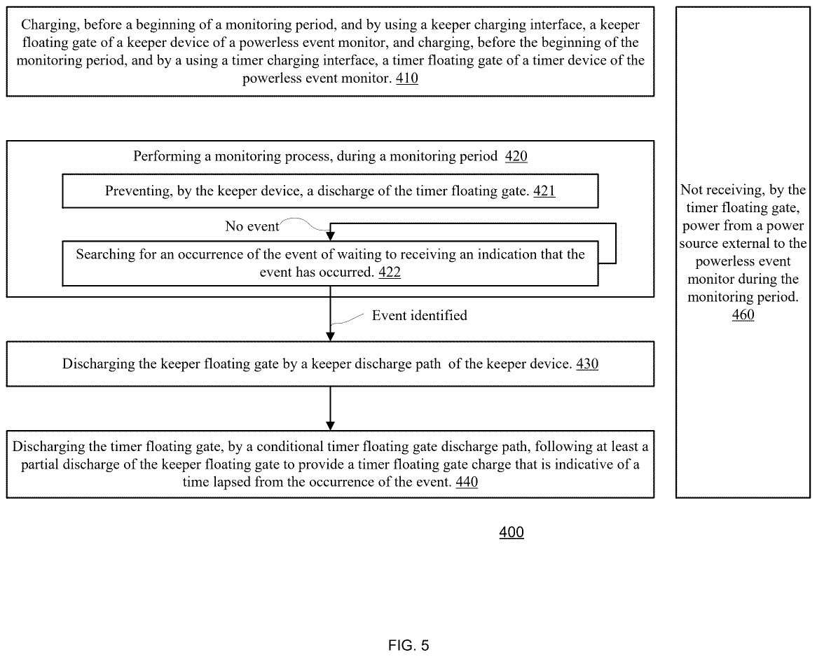

FIG. 5 illustrates an example of method 400 for powerless monitoring.

According to an embodiment, method 400 starts by step 410 of (a) charging, before a beginning of a monitoring period, and by using a keeper charging interface, a keeper floating gate of a keeper device of a powerless event monitor, and (b) charging, before the beginning of the monitoring period, and by using a timer charging interface, a timer floating gate of a timer device of the powerless event monitor. The timer device is coupled to the keeper device, the keeper device has a keeper retention time. The timer device has a timer retention time that is a fraction of the keeper retention time.

According to an embodiment, the timer device is coupled to the keeper device by providing a coupling between the keeper floating gate and the timer floating gate.

According to an embodiment, the coupling is a capacitive coupling.

According to an embodiment, at least a portion of the keeper floating gate and at least a portion of the timer floating gate form a capacitor.

According to an embodiment, the keeper floating gate includes keeper floating gate fingers, the timer floating gate includes timer floating gate fingers, wherein the keeper floating gate fingers and the timer floating gate fingers are arranged in an interdigitated configuration—to form a capacitor.

According to an embodiment, step 410 is followed by step 420 of performing a monitoring process, during the monitoring period.

According to an embodiment, step 421 includes preventing, by the keeper device, a discharge of the timer floating gate.

According to an embodiment, step 422 includes searching for an occurrence of the event of waiting to receiving an indication that the event has occurred.

At the absence of the event, step 422 is followed by itself.

According to an embodiment, steps 410, 420, 430, 440 and 460 are executed by a powerless event monitor. According to an embodiment, the event is detected by an event sensing unit.

According to an embodiment, the powerless event monitor does not include the event sensing unit and step 422 includes receiving an indication that the event has occurred.

According to an embodiment, the keeper device is in communication with an event sensing unit that is configured to sense the occurrence of the event—and step 422 includes receiving an indication that the event has occurred. According to an embodiment step 422 includes receiving, by the keeper discharge path, a signal from the event sensing unit that triggers the discharging of the keeper floating gate.

According to an embodiment, the sensing of the event includes sensing at least one of radiation, temperature, pressure, a change of radiation, a change of temperature, a change of position, and the like.

According to an embodiment, a movement of a monitored element is detected by a movement sensor such as a piezoelectric generator that is shaped and position to undergo a pressure difference when the monitored element is moved and/or by detecting radiation that is changed (for example—having a radiations source be concealed or exposed due to said movement). A monitored element may be a door—for example a door of a safe, a room or an area that should not be entered without authorization, and the like.

According to an embodiment, the event sensing unit includes one or more photodiodes and the method includes generating by the one or more photodiodes a current when exposed to radiation—or receiving an event indication generated by the one or more photodiodes.

According to an embodiment, the event sensing unit includes a piezoelectric generator and the method includes generating by the piezoelectric generator an electrical signal under pressure, the pressure being indicative of the occurrence of the event—or receiving an event indication generated by the piezoelectric generator.

According to an embodiment, the event sensing unit includes a Seebeck thermal electrical generator (or any other temperature sensor) and the method includes generating by the Seebeck thermal electrical generator (or the any other temperature sensor) an indication that the temperature of the environment of the powerless event monitor has changes and/or reached a triggering value—or receiving an event indication generated by the Seebeck thermal electrical generator (or by the any other temperature sensor).

According to an embodiment, the event sensing unit is configured to sense an event that includes a temperature change.

According to an embodiment, the event sensing unit comprises a dielectric layer with temperature dependent conductivity that is formed on the keeper floating gate—and the method includes changing the conductivity of thee dielectric layer to allow the discharging of the keeper floating gate—through the oxide layer.

When an event occurs, step 420 is followed by step 430 of discharging the keeper floating gate by a keeper discharge path of the keeper device.

According to an embodiment, step 430 is followed by step 440 of discharging the timer floating gate, by a conditional timer floating gate discharge path, following at least a partial discharge of the keeper floating gate to provide a timer floating gate charge that is indicative of a time lapsed from the occurrence of the event.

According to an embodiment, method 400 also includes step 460 not receiving, by the timer floating gate, power from a power source external to the powerless event monitor during the monitoring period. Step 460 is executed during the monitoring period.

According to an embodiment, step 460 also includes not receiving, by the keeper floating gate, power from an external power source during the monitoring period—and the only power that can received during the monitoring period is generated due to the occurrence of the event.

Assuming that the keeper floating gate is initially positively charged—then the discharging of the keeper floating gate may include injecting electrons to the keeper floating gate and/or removing holes from the keeper floating gate.

Assuming that the times floating gate is initially negatively charged—then the discharging of the timer floating gate may include injecting holes to the timer floating gate and/or removing electrons from the timer floating gate.

Any reference to a positive charge should be applied mutatis mutandis to a negative charge.

Any reference to one type of doped semiconductor (positive type or negative type) should be applied, mutatis mutandis to the other type of doped semiconductor (negative type or positive type respectively).

FIG. 5 illustrates an example of a keeper device 510 and a timer device 511 that are used to determine a timing of an exposure of an array 500 of pairs to radiation. Each pair includes a nonvolatile memory (NVM) cell 555 that is charged by a photodiode sub-arrays 520 to store a charge that are indicative of the radiation that the photodiode sub-array was charged to. One or more PD sub-array may be exposed to radiation and one or more PD sub-array may be exposed to radiation.

The values stored in the NVM cells may be single bit values (exposed tor adiation or not exposed to radiation) of multi-bit values that provide more information about the dose of the exposed radiation.

According to an embodiment, the array is read using an RFID reader. As in a typical passive RFID systems with energy harvesting and wireless power transfer functions. The external RFID reader triggers transmitting the data stored in the “keeper” array. Energy for this transmitting is harvested from the RF signal coming from the RFID reader. There is a need to transfer a single picture. The energy can be stored, e.g. on a capacitor, for a rather long time (e.g. several seconds). Thus, RF signal can be weak.

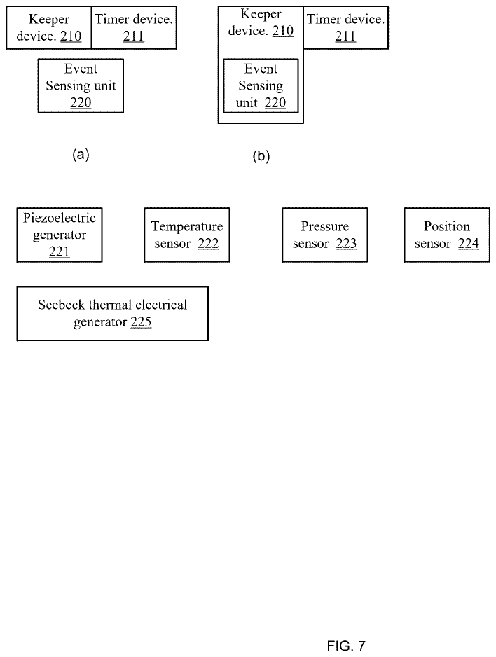

FIG. 7 illustrates examples of keeper devices, event sensing unit 220 and timer device 211.

In example (a) the event sensing unit 220 is not a part of keeper device 210.

In example (b) the event sensing unit 220 is a part of keeper device 210.

FIG. 7 also illustrates examples of event sensing unit—Seebeck thermal electrical generator 225, piezoelectric generator 221, temperature sensor 222 (other than the Seebeck thermal electrical generator), pressure sensor 223 (other than piezoelectric generator), positions sensor 224 and

Any reference to any of the terms “comprise”, “comprises”, “comprising” “including”, “may include” and “includes” may be applied mutatis mutandis to any of the terms “consists of”, “consisting”, “consisting essentially of”. For example—any of the rectifying circuits illustrated in any figure may include more components than those illustrated in the figure, only the components illustrated in the figure or substantially only the components illustrated in the figure.

In the foregoing detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “proximal”, “distal”, “front”, “back,” “top”, “bottom”, “over”, “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also, for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe.

Thus, these terms are not necessarily intended to indicate temporal or other prioritization of such elements.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim

1. A powerless event monitor, comprising:
a keeper device that exhibits a keeper retention time and comprises (a) a keeper floating gate, (b) a keeper charging interface that is configured to charge the keeper floating gate before a beginning of a monitoring period, and (c) a keeper discharge path that is triggered to discharge the keeper floating gate upon an occurrence of an event during the monitoring period; and
a timer device that is coupled to the keeper device, has a timer retention time that is a fraction of the keeper retention time, and comprises (a) a timer floating gate, (b) a timer charging interface that is configured to charge the timer floating gate before the beginning of the monitoring period, and (c) a conditional timer floating gate discharge path that is configured to discharge the timer floating gate following at least a partial discharge of the keeper floating gate, wherein a charge of the timer floating gate during the discharging of the time floating gate is indicative of a time lapsed from the occurrence of the event; and
wherein the timer device is prevented from being powered from a power source external to the powerless event monitor during the monitoring period.

2. The powerless event monitor according to claim 1, comprising an event sensing unit that is configured to sense the occurrence of the event.

3. The powerless event monitor according to claim 1, wherein the keeper device comprises an event sensing unit that is configured to sense the occurrence of the event.

4. The powerless event monitor according to claim 1, wherein the keeper device is in communication with an event sensing unit that is configured to sense the occurrence of the event.

5. The powerless event monitor according to claim 1, wherein the keeper discharge path is triggered by an event sensing unit that is configured to sense the occurrence of the event.

6. The powerless event monitor according to claim 5, wherein the event sensing unit comprises one or more photodiodes that are configured to generate current when exposed to radiation.

7. The powerless event monitor according to claim 5, wherein the event sensing unit comprises a piezoelectric generator configured to generate an electrical signal under pressure, the pressure being indicative of the occurrence of the event.

8. The powerless event monitor according to claim 5, wherein the event sensing unit comprises a seebeck thermal electrical generator.

9. The powerless event monitor according to claim 5, wherein the event sensing unit is configured to sense an event that includes a temperature change.

10. The powerless event monitor according to claim 5, wherein the event sensing unit comprises a dielectric layer with temperature dependent conductivity that is formed on the keeper floating gate.

11. The powerless event monitor according to claim 1, wherein the keeper device comprises a keeper tunneling oxide layer, the timer device comprises a timer tunnelling oxide layer of a thickness that ranges between thirty to fifty Angstrom, and wherein the thickness of the keeper oxide layer exceeds the thickness of the timer oxide layer.

12. The powerless event monitor according to claim 1, wherein the keeper floating gate comprises keeper floating gate fingers, the timer floating gate comprises timer floating gate fingers, wherein the keeper floating gate fingers and the timer floating gate fingers are arranged in an interdigitated configuration.

13. A method for powerless monitoring, the method comprises:
charging, before a beginning of a monitoring period, and by using a keeper charging interface, a keeper floating gate of a keeper device of a powerless event monitor;
charging, before the beginning of the monitoring period, and by a using a timer charging interface, a timer floating gate of a timer device of the powerless event monitor; wherein the timer device is coupled to the keeper device, the keeper device has a keeper retention tome, and the timer device has a timer retention time that is a fraction of the keeper retention time;
preventing, by the keeper device, a discharge of the timer floating gate, while an event did not occur during the monitoring period;
upon an occurrence of an event during the monitoring period, discharging the keeper floating gate by a keeper discharge path of the keeper device;
discharging the timer floating gate, by a conditional timer floating gate discharge path, following at least a partial discharge of the keeper floating gate to provide a timer floating gate charge that is indicative of a time lapsed from the occurrence of the event; and
preventing a powering of the timer floating gate by a power source external to the powerless event monitor during the monitoring period.

14. The method according to claim 13, comprising sensing the occurrence of the event by an event sensing unit.

15. The method according to claim 14, wherein the event sensing unit is located within the keeper device.

16. The method according to claim 14, wherein the sensing of the event is executed by one or more photodiodes of the event sensing unit, the one or more photodiodes are configured to generate current when exposed to radiation.

17. The method according to claim 14, wherein the sensing of the event is executed by a piezoelectric generator of the event sensing unit, the piezoelectric generator is configured to generate an electrical signal under pressure, the pressure being indicative of the occurrence of the event.

18. The method according to claim 14, wherein the sensing of the event is executed by a seebeck thermal electrical generator.

19. The method according to claim 14, wherein the sensing of the event comprises sensing a temperature change.

20. The method according to claim 14, wherein the event sensing unit comprises a dielectric layer with temperature dependent conductivity that is formed on the keeper floating gate.
